(19) United States
(12) Patent Application Publication
(10) Pub. No.: US 2026/0324269 A1
(43) Pub. Date: Oct. 15, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-si (KR)

(72) Inventors: Gyung Min BAEK, Yongin-si (KR); Do Keun SONG, Yongin-si (KR); Byung Soo SO, Yongin-si (KR)

(73) Assignee: Samsung Display Co., Ltd., Yongin-si (KR)

(21) Appl. No.: 19/640,101

(22) Filed: Apr. 6, 2026

(30) Foreign Application Priority Data
Apr. 9, 2025 (KR) 10-2025-0045876

(51) Int. Cl. H10K 59/80; H10K 59/12; H10K 102/00

(52) U.S. Cl. CPC H10K 59/8792; H10K 59/1201; H10K 2102/351

(57) ABSTRACT

A display device includes a base stack and a display structure including a light-emitting element and on the base stack. The base stack may include a base substrate, a blocking layer on the base substrate and including at least one of a metal oxide, a metal nitride, or a metal carbide, and a metal layer on the blocking layer and spaced apart from the base substrate with the blocking layer therebetween.

### CROSS-REFERENCE TO RELATED APPLICATION

This U.S. non-provisional application claims priority under 35 U.S.C. § 119 to Korean Patent Application No. 10-2025-0045876 filed on Apr. 9, 2025, in the Korean Intellectual Property Office (KIPO), the entire disclosure of which is incorporated by reference herein.

### BACKGROUND

Some example embodiments of the present disclosure relate to a display device including a base stack and a display structure, a method of manufacturing the display device, and an electronic device including the display device.

In a display device such as an organic light emitting diode (OLED) display device and a liquid crystal display (LCD) device, a display substrate including, e.g., a thin film transistor (TFT) and wirings may be provided, and a display structure including electrodes and emission layers may be formed on the display substrate. For example, an OLED display device may include a light-emitting element including an organic emission layer.

An external light or a light generated from the light-emitting element may be reflected by electrodes included in the display device, thereby reducing an image quality and optical properties of the display device.

### SUMMARY

According to some example embodiments of the present disclosure, there is provided a display device having improved optical property and/or image reliability.

According to some example embodiments of the present disclosure, there is provided a method of manufacturing a display device having improved optical property and/or image reliability.

According to some example embodiments of the present disclosure, there is provided an electronic device including a display device with improved optical property and/or image reliability.

According to some example embodiments, a display device may include a base stack and a display structure on the base stack. The display structure includes a light-emitting element. The base stack may include a base substrate, a blocking layer on the base substrate and including at least one of a metal oxide, a metal nitride, and a metal carbide, and a metal layer on the blocking layer and spaced apart from the base substrate with the blocking layer therebetween.

In some example embodiments, the blocking layer may include at least one of a molybdenum oxide-based material, a copper oxide-based material, a copper nitride-based material, or a niobium carbide-based material.

In some example embodiments, the blocking layer may include molybdenum-tantalum oxide.

In some example embodiments, the blocking layer may contact the base substrate, and the metal layer may contact the blocking layer.

In some example embodiments, the blocking layer may have a reflectance of less than 10% and a transmittance of less than 10% for a light having a wavelength of 550 nm.

In some example embodiments, the blocking layer may have a transmittance of less than 1.0*10⁻¹²% for the light having the wavelength of 550 nm.

In some example embodiments, the blocking layer may have a thickness of 400 Å to 650 Å.

In some example embodiments, the base stack may further include a buffer insulating layer, and an antistatic layer including a metal nitride.

In some example embodiments, the buffer insulating layer may include at least one of silicon oxide, silicon nitride, silicon oxynitride, or a metal oxide.

In some example embodiments, the antistatic layer may include titanium nitride.

In some example embodiments, a resistivity of the antistatic layer may be in a range from 100 μΩ·cm to 500 μΩ·cm, and a sheet resistance of the antistatic layer may be in a range from 5 Ω/□ to 100 Ω/□.

In some example embodiments, a pencil hardness of the base stack measured from a surface of the antistatic layer may be 5 H or higher.

In some example embodiments, the base substrate may have a first surface and a second surface opposite each other. The display structure may be on the first surface of the base substrate. The blocking layer, the metal layer, the buffer insulating layer, and the antistatic layer may be sequentially on the second surface of the base substrate.

In some example embodiments, the base substrate may have a first surface and a second surface opposite each other. The blocking layer, the metal layer, and the buffer insulating layer may be sequentially on the first surface of the base substrate. The antistatic layer may be on the second surface of the base substrate. The display structure may be on the buffer insulating layer.

According to some example embodiments, a method for manufacturing a display device includes providing a base substrate having a first surface and a second surface opposite the first surface. A blocking layer including at least one of a metal oxide, a metal nitride, or a metal carbide may be formed by a deposition process on the first surface or the second surface of the base substrate. A metal layer may be formed on the blocking layer by a deposition process. A display structure including a light-emitting element may be formed on the first surface of the base substrate.

In some example embodiments, a buffer insulating layer and an antistatic layer that includes a metal nitride may be further formed on the metal layer by a deposition process. The blocking layer, the metal layer, the buffer insulating layer, and the antistatic layer may be sequentially formed from the second surface of the base substrate.

In some example embodiments, a buffer insulating layer may be formed on the metal layer on the first surface of the base substrate by a deposition process. An antistatic layer that includes a metal nitride may be formed on the second surface of the base substrate after forming the display structure. The blocking layer, the metal layer, and the buffer insulating layer may be sequentially formed from the first surface of the base substrate.

In some example embodiments, a thickness of the base substrate may be reduced before forming the antistatic layer.

According to some example embodiments, an electronic device may include a display device, a memory, and a processor executing data included in the memory to control an operation of the display device. The display device may include a base stack and a display structure including a light-emitting element and on the base stack. The base stack may include a base substrate, a blocking layer formed on the base substrate and including at least one selected from the group consisting of a metal oxide, a metal nitride and a metal carbide, and a metal layer formed on the blocking layer and spaced apart from the base substrate with the blocking layer therebetween.

In some example embodiments, the electronic device may include virtual reality or augmented reality glasses, a smartphone, a tablet personal computer (PC), a laptop, a television, a desk monitor, smart glasses, a head-mounted display, a smart watch, or a vehicle display.

According to some example embodiments of the present disclosure, light-shielding properties, mechanical stability, resistance properties for reducing or limiting static electricity, and process stability of a display device may be improved using a base stack including a base substrate.

According to some example embodiments, layers included in the base stack may be formed using a deposition process. Accordingly, the layers of the base stack may be formed having improved stability on a relatively large-scaled and thinner substrate, and process yield and reliability may also be improved.

### BRIEF DESCRIPTION OF THE DRAWINGS

FIG. 1 is a schematic plan view of a display device according to some example embodiments.

FIG. 2 is a pixel equivalent circuit diagram of a display device according to some example embodiments.

FIG. 3 is a schematic cross-sectional view illustrating a display device according to some example embodiments.

FIG. 4 is a schematic view for describing a light-shielding mechanism by a blocking layer and a metal layer according to some example embodiments.

FIG. 5 is a graph showing a change in reflectance according to a thickness of a blocking layer.

FIG. 6 is a graph showing a change in transmittance according to a thickness of a blocking layer.

FIGS. 7 and 8 are cross-sectional views illustrating a method of manufacturing a display device according to some example embodiments.

FIG. 9 is a schematic cross-sectional view illustrating a display device according to some example embodiments.

FIGS. 10, 11, 12, and 13 are cross-sectional views illustrating a method of manufacturing a display device according to some example embodiments.

FIG. 14 is an exploded perspective view of a display device according to some example embodiments.

FIG. 15 is a block diagram of an electronic device according to some example embodiments.

FIG. 16 is a schematic diagram of electronic devices according to some example embodiments.

### DETAILED DESCRIPTION OF EXAMPLE EMBODIMENTS

Hereinafter, some example embodiments of the present disclosure will be described in more detail with reference to the attached drawings. The same reference numerals can be used for indicating the same elements in the drawings, and repeated descriptions of the same elements can be omitted. Example embodiments disclosed in the attached drawings are mere examples, and are to be understood to include all modifications, equivalents, and substitutes included in the spirit and technical scope of the present disclosure.

The terms “on”, “connected”, “coupled,” etc., used herein refer to a direct placement/connection/combination, and also refer to a case where another element is interposed between two different elements.

The terms such as “first”, “second”, “below”, “under”, “above,” “on,” etc., are used in a relative sense to distinguish different elements or positions, and do not specify an absolute position or an absolute order.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween, such as increments of 0.1%.

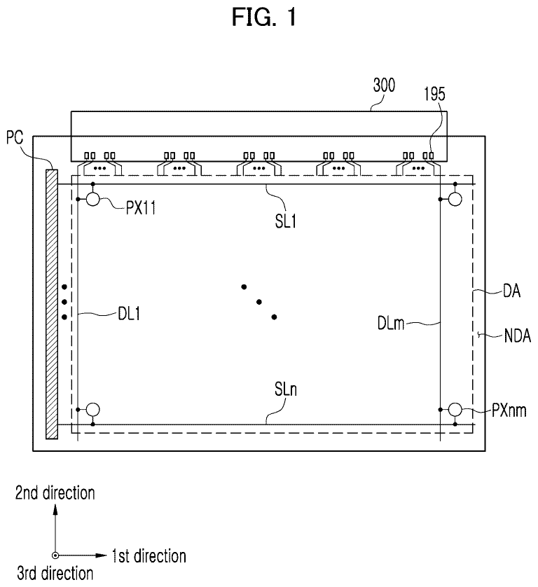

FIG. 1 is a schematic plan view illustrating a display device according to some example embodiments. For example, FIG. 1 is a plan view illustrating a pixel arrangement of a display device according to some example embodiments.

In FIG. 1, a first direction and a second direction may refer to two directions parallel to a display surface of a display device and orthogonal to each other. For example, the first direction may correspond to an X-direction (e.g., a row direction) of the display device, and the second direction may correspond to a Y-direction (a column direction) of the display device. A third direction may be perpendicular to the first direction and the second direction. The third direction may correspond to a Z-direction (a thickness direction) of the display device.

In the accompanying drawings, the above definition of the directions may be equally applied.

Referring to FIG. 1, a plurality of pixels PX11 to PXnm may be arranged in a display area DA of the display device.

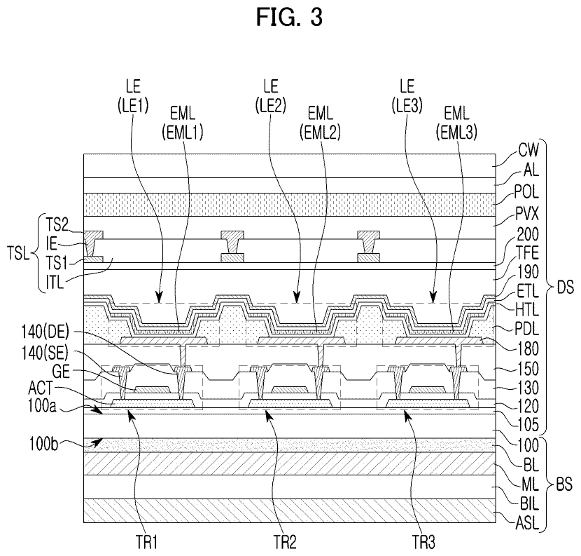

In some example embodiments, a pixel circuit including scan lines SL1 to SLn (or gate lines) forming first to n^{th} rows, and data lines DL1 to DLm forming first to m^{th} columns may be arranged on a base substrate 100 (see FIG. 3) of the display device. Each of the pixels PX11 to PXnm may be connected to a scan line of a corresponding row among a plurality of scan lines SL1 to SLn and a data line of a corresponding column among a plurality of data lines DL1 to DLm.

Each of the pixels PX11 to PXnm may further include a pixel circuit including a transistor and a light-emitting element as described below. The pixel circuit of FIG. 1 may further include wirings such as a power line, a ground line, etc.

FIG. 1 illustrates that the data lines DL1 to DLm extend in the second direction and the scan lines SL1 to SLn extend in the first direction, but the arrangement of the data lines and the gate lines is not limited to that illustrated in FIG. 1.

The display device of FIG. 1 may include a display area DA and a non-display area NDA along a peripheral area of the display area DA. A peripheral circuit PC may be disposed in the non-display area NDA corresponding to the peripheral area of the display area DA. For example, the peripheral circuit PC may be or include a gate driving circuit. The gate driving circuit may be integrated into the display panel DP by an oxide semiconductor gate (OSG) driver circuit process, an amorphous silicon gate (ASG) driver circuit process, or a polysilicon gate (PSG) driver circuit process.

The peripheral circuit PC may further include a data driver, a gate driver, a light-emitting driver, a power voltage generator, a timing controller, or the like.

The display device may further include a printed circuit board 300. Pads 195 of the pixel circuit may be assembled or arranged at one end portion of the non-display area NDA. The printed circuit board 300 may be electrically connected to the pixel circuit through the pads 195. For example, the printed circuit board 300 may be electrically connected to the pads 195 by a heat-compression process using a conductive intermediate structure such as an anisotropic conductive film (ACF).

An integrated circuit (IC), such as a data driving circuit, may be disposed on the printed circuit board 300. In some example embodiments, an integrated circuit (IC) chip in the form of a chip-on-film (COF) may be mounted on the printed circuit board 300.

Hereinafter, the construction/structure of the display device of the present disclosure may be described using an organic light-emitting display device as an example. However, the display device of the present disclosure may also be used in various types of display devices such as an inorganic light-emitting display device, a quantum dot light-emitting display device, and the like.

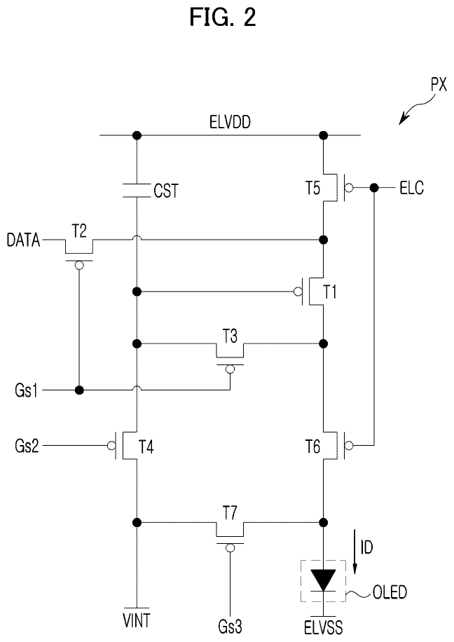

FIG. 2 is a pixel equivalent circuit diagram of a display device according to some example embodiments.

Referring to FIG. 2, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal, and a second terminal. The gate terminal may be connected to the storage capacitor CST. The first terminal may be connected to the second transistor T2. The second terminal may be connected to the sixth transistor T6. The first transistor T1 may generate a driving current ID based on a voltage difference between the gate terminal and the first terminal. For example, the first transistor T1 may be referred to as a driving transistor.

The second transistor T2 may include a gate terminal, a first terminal, and a second terminal. The gate terminal of the second transistor T2 may receive a first gate signal Gs1. The second transistor T2 may be turned on or turned off in response to the first gate signal Gs1. The first terminal of the second transistor T2 may receive a data voltage DATA. The second transistor T2 may provide the data voltage DATA to the first terminal of the first transistor T1 in response to the first gate signal Gs1. For example, the second transistor T2 may be referred to as a switching transistor.

The third transistor T3 may include a gate terminal, a first terminal, and a second terminal. The gate terminal may receive the first gate signal Gs1. The first terminal may be connected to the gate terminal of the first transistor T1. The second terminal may be connected to the second terminal of the first transistor T1. The third transistor T3 may compensate for a threshold voltage of the first transistor T1. For example, the third transistor T3 may serve as a compensation transistor.

The fourth transistor T4 may include a gate terminal, a first terminal, and a second terminal. The gate terminal may receive a second gate signal Gs2. The first terminal may be connected to the gate terminal of the first transistor T1. The second terminal may receive an initialization voltage VINT. The fourth transistor T4 may initialize the gate terminal of the first transistor T1.

The fifth transistor T5 may include a gate terminal, a first terminal, and a second terminal. The gate terminal may receive an emission control signal ELC. The first terminal may receive a high-power supply voltage ELVDD. The second terminal may be connected to the first transistor T1.

The sixth transistor T6 may include a gate terminal, a first terminal, and a second terminal. The gate terminal may receive the emission control signal ELC. The first terminal may be connected to the first transistor T1. The second terminal may be connected to an organic light-emitting diode OLED. The sixth transistor T6 may transfer the driving current ID to the organic light emitting diode OLED in response to the emission control signal ELC.

The seventh transistor T7 may include a gate terminal, a first terminal, and a second terminal. The gate terminal may receive a third gate signal Gs3. The first terminal may be connected to the organic light-emitting diode OLED. The second terminal may receive the initialization voltage VINT. The seventh transistor T7 may initialize the organic light-emitting diode OLED.

The storage capacitor CST may include a first terminal and a second terminal. The first terminal may receive the high-power supply voltage ELVDD. The second terminal may be connected to the gate terminal of the first transistor T1.

The organic light-emitting diode OLED may include a first terminal and a second terminal. The first terminal may be connected to the sixth transistor T6. The second terminal may receive a low-power supply voltage ELVSS. The organic light-emitting diode OLED may emit light based on the driving current ID.

FIG. 2 illustrates a 7T1C structure including seven thin film transistors and one storage capacitor CST in each pixel PX, but the pixel structure of the display device disclosed herein is not limited thereto.

For example, each pixel PX may include two or more transistors, and may have a structure such as 2T1C, 5T1C, 6T1C, 5T2C, 6T2C, or the like.

FIG. 3 is a schematic cross-sectional view illustrating a display device according to some example embodiments.

Referring to FIG. 3, the display device may include a base stack BS, and a display structure DS disposed or arranged or formed on the base stack BS. The display structure DS may include a pixel circuit including transistor structures TR1, TR2, and TR3 and the light-emitting element LE.

The base stack BS may include the base substrate 100. The base substrate 100 may serve or function as a back-plane substrate of a display device. A glass substrate, a ceramic substrate, or a plastic substrate may be used as the base substrate 100. In some example embodiments, the base substrate 100 may include a polymer material having transparency and flexibility. In some example embodiments, the base substrate 100 may be used in a transparent flexible display device.

For example, the base substrate 100 may include a polymer material such as polyimide, polysiloxane, an epoxy resin, an acrylic resin, polyester, or the like. In some example embodiments, the base substrate 100 may include polyimide.

According to some example embodiments, the base substrate 100 may be a thin glass substrate having a thickness in a range of 0.1 T to 0.3 T (T denotes mm).

The base substrate 100 may have a first surface 100a and a second surface 100b opposite each other. The first surface 100a may be a surface facing a front portion of the display device. The first surface 100a may be a surface of a display device on which the display structure DS is stacked. The second surface 100b may be a surface facing a rear portion of the display device.

The first surface 100a and the second surface 100b may correspond to a front surface and a rear surface of the base substrate 100, respectively.

The base stack BS may include a blocking layer BL and a metal layer ML. The base stack BS may further include a buffer insulating layer BIL and an antistatic layer ASL.

According to some example embodiments, the blocking layer BL, the metal layer ML, the buffer insulating layer BIL, and the antistatic layer ASL may be sequentially stacked in a downward direction (a rear direction) from the second surface 100b of the base substrate 100.

The blocking layer BL may be provided or configured as a light-absorbing layer or a blackened layer. The blocking layer BL may prevent, or reduce, or limit external light from being reflected to enter or be incident on the light-emitting element LE included in the display structure DS, and may enhance or improve optical properties of the display device. Further, a light incident on the light-emitting element LE from the rear portion may be blocked or a transmission thereof may be impeded by the blocking layer BL.

According to some example embodiments, the blocking layer BL may have a reflectance less than 10% and a transmittance less than 10% with respect to a light having a wavelength of 550 nm (or about 550 nm). In some example embodiments, the blocking layer BL may have a transmittance of 5% (or about 5%) or less, 1% (or about 1%) or less, 0.1% (or about 0.1%) or less, 0.01% (or about 0.01%) or less, or 1.0*10⁻¹²% (or about 1.0*10⁻¹²%) or less with respect to the light having a wavelength of 550 nm.

The blocking layer BL may include a material capable of or configured for providing the above-described blackening and optical properties. The blocking layer BL may include a metal oxide, a metal nitride, a metal carbide, or a combination thereof. In some example embodiments, the blocking layer BL may include a molybdenum oxide-based material, a copper oxide-based material, a copper nitride-based material, a niobium carbide-based material, or the like.

In some example embodiments, the blocking layer BL may include a molybdenum oxide-based material. In some example embodiments, the molybdenum oxide-based material may further include a dopant. Moisture stability of the blocking layer BL may be enhanced or improved or increased by the dopant, and mechanical and chemical stability of the base stack BS at, e.g., room temperature may be improved.

In some example embodiments, the dopant may include tantalum (Ta) and/or tungsten (W). A content of the dopant in the molybdenum oxide-based material may be in a range from 1 at % (or about 1 at %) to 10 at % (or about 10 at %), from 3 at % (or about 3 at %) to 10 at % (or about 10 at %), or from 5 at % (or about 5 at %) to 10 at % (or about 10 at %). In the above range, moisture stability may be improved while maintaining the blackening properties of molybdenum.

For example, the blocking layer BL may include a molybdenum-tantalum oxide (MoTaOₓ), and a content of tantalum in the molybdenum-tantalum oxide may be in a range from 1 at % (or about 1 at %) to 10 at % (or about 10 at %), from 3 at % (or about 3 at %) to 10 at % (or about 10 at %), or from 5 at % (or about 5 at %) to 10 at % (or about 10 at %).

A thickness of the blocking layer BL may be adjusted in a range from 400 Å (or about 400 Å) to 650 Å (or about 650 Å), from 450 Å (or about 450 Å) to 650 Å (or about 650 Å), or from 500 Å (or about 500 Å) to 650 Å (or about 650 Å).

In some example embodiments, the blocking layer BL may be in direct contact with a surface of the base substrate 100 (e.g., the second surface 100b).

As will be described below, the metal layer ML may be used together with the blocking layer BL to further enhance light-absorption or blackening properties. The metal layer ML may include a metal such as Al, Mo, Cu, Ag, Pt, Pd, Au, Ni, Nd, Ir, Cr, Li, Ca, Ti, W, In, Sn, Zn, or an alloy of two or more thereof.

In some example embodiments, the metal layer ML may include at least one of Al, Mo, Cu, or Ag. A thickness of the metal layer ML may be adjusted to prevent or limit or reduce an external light transmission. For example, the metal layer ML may have a thickness greater than or equal to a skin depth of the included metal.

In some example embodiments, the thickness of the metal layer ML may be adjusted to be greater than or equal to 600 Å (or about 600 Å), e.g., in a range from 600 Å (or about 600 Å) to 1,500 Å (or about 1,500 Å). In some example embodiments, the thickness of the metal layer ML may be in a range from 600 Å (or about 600 Å) to 1,000 Å (or about 1,000 Å), from 650 Å (or about 650 Å) to 1,500 Å (or about 1,500 Å), from 650 Å (or about 650 Å) to 1,000 Å (or about 1,000 Å), from 700 Å (or about 700 Å) to 1,500 Å (or about 1,500 Å), from 700 Å (or about 700 Å) to 1,000 Å (or about 1,000 Å), from 800 Å (or about 800 Å) to 1,500 Å (or about 1,500 Å), or from 800 Å (or about 800 Å) to 1,000 Å (or about 1,000 Å).

According to some example embodiments, the metal layer ML may directly contact the blocking layer BL. In the cross-section of FIG. 3, a top surface of the metal layer ML may directly contact a bottom surface of the blocking layer BL. The metal layer ML may be formed on the base substrate 100 and spaced apart from the base substrate 100 with the blocking layer BL therebetween.

The buffer insulating layer BIL may include an inorganic insulating material and/or an organic insulating material. In some example embodiments, the buffer insulating layer BIL may include an inorganic insulating material. In some example embodiments, the buffer insulating layer BIL may also be formed in a relatively larger area with relative ease using a deposition process.

For example, the buffer insulating layer BIL may include an insulating metal oxide such as silicon oxide, silicon nitride, silicon oxynitride, aluminum oxide, or the like. These may be used alone or in a combination of two or more thereof.

Surface resistance properties from the antistatic layer ASL may be adjusted by the buffer insulating layer BIL.

The antistatic layer ASL may be included or configured as a functional layer for improving surface hardness and surface resistance properties of the base stack BS. A pencil hardness of the base stack BS measured from a surface of the antistatic layer ASL may be 2 H or more, 3 H or more, 4 H or more, or 5 H or more. According to some example embodiments, the pencil hardness of the base stack BS measured from the surface of the antistatic layer ASL may be 5 H or more. For example, the pencil hardness may be measured based on a standard of JIS-K5400-1990.

A sheet resistance of the antistatic layer ASL may be 10¹⁰ Ω/□ (or about 10¹⁰ Ω/□) or less. According to some example embodiments, the sheet resistance of the antistatic layer ASL may be adjusted in a range from 5 Ω/□ (or about 5 Ω/□) to 100 Ω/□ (or about 100 Ω/□), from 5 Ω/□ (or about 5 Ω/□) to 50 Ω/□ (or about 50 Ω/□), from 5 Ω/□ (or about 5 Ω/□) to 30 Ω/□ (or about 30 Ω/□), or 5 Ω/□ (or about 5 Ω/□) to 20 Ω/□ (or about 20 Ω/□).

In some example embodiments, a resistivity of the antistatic layer ASL may be adjusted in a range from 100μΩ·cm (or about 100μΩ·cm) to 500μΩ·cm (or about 500 μΩ·cm), or from 100μΩ·cm (or about 100μΩ·cm) to 400μΩ·cm (or about 400μΩ·cm).

A thickness and a material of the antistatic layer ASL may be selected in consideration of the above-described surface resistance and the hardness properties.

In some example embodiments, the antistatic layer ASL may include a metal nitride. The antistatic layer ASL may include a nitride of titanium, tantalum, and/or tungsten. In some example embodiments, the antistatic layer ASL may include titanium nitride.

In the cross-section of FIG. 3, the buffer insulating layer BIL may be disposed between the metal layer ML and the antistatic layer ASL. The buffer insulating layer BIL may be in direct contact with a top surface of the antistatic layer ASL. The buffer insulating layer BIL may be in direct contact with a bottom surface of the metal layer ML.

Accordingly, a resistance change or variation between the metal layer ML and the antistatic layer ASL may be controlled through the buffer insulating layer BIL.

According to some example embodiments, reflection/transmission of the base stack BS may be suppressed or reduced by the combination of the blocking layer BL and the metal layer ML, and light-shielding properties may be sufficiently, adequately, or desirably implemented. Additionally, surface hardness and antistatic properties at the rear portion may be effectively implemented by the buffer insulating layer BIL and the antistatic layer ASL.

The display structure DS may be stacked on the base substrate 100. As described above, the display structure DS may include transistor structures TR1, TR2, and TR3 and the light-emitting element LE. The display structure DS may further include a touch sensor layer TSL, a polarizing plate POL, a cover window CW, or the like.

A barrier layer 105 may be formed on the base substrate 100. Moisture penetrating through the base substrate 100 may be blocked or restricted by the barrier layer 105, and diffusion of impurities between the base substrate 100 and structures formed on the base substrate 100 may also be blocked or restricted by the barrier layer 105. The barrier layer 105 may be formed over the entire display area DA and the non-display area NDA of the base substrate 100, and may cover an entire top surface of the base substrate 100.

The barrier layer 105 may include, e.g., an inorganic insulating material such as silicon oxide, silicon nitride, or silicon oxynitride. These may be used alone or in a combination of two or more thereof. In some example embodiments, the barrier layer 105 may have a stacked structure including a silicon oxide layer and a silicon nitride layer. The barrier layer 105 may be formed by a deposition process such as a chemical vapor deposition (CVD) process, a sputtering process, an atomic layer deposition (ALD) process, or the like, and may include the inorganic insulating material described above.

In some example embodiments, the barrier layer 105 may include an organic layer, and may have a multi-layered structure of the organic layer and the inorganic layer.

The pixel circuit may include wirings including the scan lines and the data lines described with reference to FIG. 1, and the transistor structures TR1, TR2, and TR3 electrically interacting with the wirings. The transistor structures TR1, TR2, and TR3 may be electrically connected to the light-emitting elements LE1, LE2, and LE3.

The transistor structures TR1, TR2, and TR3 may include an active layer ACT, a gate insulation layer 120, and a gate electrode GE.

The active layer ACT may be disposed on the barrier layer 105, and may be patterned by, e.g., a photo-lithography process, and the active layer ACT may be repeatedly or regularly arranged on the barrier layer 105. The active layer ACT may include a silicon-based material such as polysilicon or amorphous silicon. A p-type dopant or an n-type dopant may be doped in a partial region of the active layer ACT, so that the active layer ACT may include a source region, a drain region, and a channel region.

The active layer ACT may include an oxide semiconductor such as indium gallium zinc oxide (IGZO), zinc tin oxide (ZTO), or indium tin zinc oxide (ITZO).

The gate insulation layer 120 may be formed on the active layer ACT, and the gate electrode GE may be stacked on the gate insulation layer 120. As illustrated in FIG. 3, the gate insulation layer 120 may be continuously and commonly provided for a plurality of the transistor structures TR1, TR2, and TR3 or pixels of different colors. Alternatively, the gate insulation layer 120 may be formed in a pattern shape partially covering each active layer ACT.

The gate electrode GE may overlap (e.g., vertically overlap) the channel region of the active layer ACT in the third direction. A scan signal may be transmitted from the scan line through the gate electrode GE.

The gate insulation layer 120 may be formed by the above-mentioned deposition process and may include an inorganic insulating material such as silicon oxide, silicon nitride, silicon oxynitride, or the like.

In some example embodiments, the source region and the drain region may be formed in the active layer ACT by using the gate electrode GE as an ion implantation mask.

An insulating interlayer 130 covering the gate insulation layer 120 and the gate electrode GE may be formed on the active layer ACT. A connection electrode 140, which may be in contact with or electrically connected to the active layer ACT, may be formed on the insulating interlayer 130.

The insulating interlayer 130 may be formed by the above-mentioned deposition process and may include an inorganic insulating material such as silicon oxide, silicon nitride, silicon oxynitride, or the like. The insulating interlayer 130 may be formed in a single-layered structure or a multi-layered structure including different materials.

In some example embodiments, when the gate insulation layer 120 has an individual pattern shape and the active layer ACT includes an oxide semiconductor, hydrogen (H) included in the insulating interlayer 130 may be diffused or moved to the active layer ACT when forming the insulating interlayer 130. Accordingly, a carrier concentration may be increased by hydrogen, so that the source region and the drain region may be formed at side portions of the active layer ACT.

Each of the transistor structures TR1, TR2, and TR3 may further include the connection electrode 140. The connection electrode 140 may extend through the insulating interlayer 130, and may be connected to the active layer ACT. The connection electrode 140 may also extend through the gate insulation layer 120.

The connection electrode 140 may include a source electrode SE connected to or in contact with the source region of the active layer ACT, and a drain electrode DE connected to or in contact with the drain region of the active layer ACT.

Contact holes may be formed by partially etching the insulating interlayer 130. For example, the contact holes exposing the source region and the drain region, respectively, may be formed. The contact holes may also extend through the gate insulation layer 120 together.

A metal layer filling the contact holes may be formed on the insulating interlayer 130, and then the metal layer may be partially etched to form the source electrode SE and the drain electrode DE. For example, a data signal may be transmitted from the data line through the source electrode SE.

The gate electrode GE and the connection electrode 140 may include a metal such as Ag, Mg, Al, W, Cu, Ni, Cr, Mo, Ti, Pt, Ta, Nd, Sc, etc., an alloy thereof, or a nitride thereof. The gate electrode GE and the connection electrode 140 may be formed by the above-mentioned deposition process, such as a sputtering process. The gate electrode GE and/or the connection electrode 140 may have a multi-layered structure including different metal layers.

A planarization layer 150 covering the connection electrodes 140 may be formed on the insulating interlayer 130. The planarization layer 150 may accommodate a via portion electrically connecting a pixel electrode 180 to the drain electrode DE.

In some example embodiments, the planarization layer 150 may include an organic material such as polyimide, an epoxy resin, an acrylic resin, polyester, a siloxane resin, benzocyclobutene (BCB), or the like. The planarization layer 150 may be formed by a coating process, such as a spin coating process or the above-mentioned deposition process.

The pixel electrode 180 may be formed in each pixel to be electrically connected to the transistor structure. The pixel electrode 180 may be formed on the planarization layer 150 to be electrically connected to the drain electrode DE.

For example, the planarization layer 150 may be partially etched to form a via hole exposing a top surface of the drain electrode DE. A conductive layer including a metal material or a transparent conductive oxide and filling the via hole may be formed on a top surface of the planarization layer 150, and then the conductive layer may be etched to form the pixel electrode 180. The pixel electrode 180 may include the via portion filling the via hole.

The pixel electrode 180 may be provided as an anode and may include a relatively higher work function conductive material that may promote or improve hole injection. The pixel electrode 180 may be formed or configured as a transmissive electrode. The pixel electrode 180 may include a transparent conductive oxide, such as indium tin oxide (ITO), indium zinc oxide (IZO), zinc oxide (ZnO), indium tin oxide (ITZO), or the like.

The pixel electrode 180 may be formed or configured as a translucent electrode or a reflective electrode. The pixel electrode 180 may include a metal including, for example, Ag, Mg, Cu, Al, Pt, Pd, Au, Ni, Nd, Ir, Cr, Li, Ca, Mo, Ti, W, In, Sn, and Zn, or an alloy or a compound (LiF) containing at least one of the metals.

The pixel electrode 180 may have a single-layered structure or a multi-layered structure. For example, the pixel electrode 180 may have a triple-layered structure such as ITO/Ag/ITO or ITO/Al/ITO.

A pixel defining layer PDL exposing a top surface of the pixel electrode 180 may be formed on the planarization layer 150. The pixel defining layer PDL may have an opening through which the top surface of the pixel electrode 180 is at least partially exposed, and a pixel region may be defined by the opening. The pixel defining layer PDL may cover a peripheral portion of the pixel electrode 180.

For example, the pixel region or the light-emitting region may be defined by a sidewall of the pixel defining layer PDL. A first pixel including the first transistor structure TR1 and the first light-emitting element LE1, a second pixel including the second transistor structure TR2 and the second light-emitting element LE2, and a third pixel including the third transistor structure TR3 and the third light-emitting element LE3 may be separated from each other and defined by the pixel defining layer PDL.

In some example embodiments, the first pixel, the second pixel, and the third pixel may correspond to a red pixel, a green pixel, and a blue pixel, respectively.

The pixel defining layer PDL may include, e.g., an organic material such as a polysiloxane resin, a polyimide resin, an acrylic resin, or the like. The pixel defining layer PDL may include a colorant material such as a black pigment/dye dispersed in the resin material. The pixel defining layer PDL may include an inorganic layer such as a silicon oxide layer and/or a silicon nitride layer.

In some example embodiments, the pixel defining layer PDL may have a stepped structure as illustrated in FIG. 3.

An emission layer EML may be disposed on the exposed surface of the pixel electrode 180. In some example embodiments, the emission layer EML may include an organic light-emitting material that may be independently patterned for each red pixel, a green pixel, and a blue pixel to generate different colored light for each pixel.

The emission layer EML may include a first emission layer EML1 that may be included in the first pixel and may include a red organic light-emitting material, a second emission layer EML2 that may be included in the second pixel and may include a green organic light-emitting material, and a third emission layer EML3 that may be included in the third pixel and may include a blue organic light-emitting material.

For example, the organic light-emitting material may include a host material excited by a hole and an electron, and a dopant material that may increase luminous efficiency through absorption and release of energy.

In some example embodiments, a hole transport layer HTL may be disposed between the pixel electrode 180 and the emission layer EML. An electron transport layer ETL may be disposed on the emission layer EML.

The hole transport layer HTL and the electron transport layer ETL may extend continuously and commonly across a plurality of the light-emitting elements LE and the pixels.

For example, the hole transport layer HTL may include a hole transporting material such as m-MTDATA (4,4′,4″-Tris[(3-methylphenyl)phenylamino]triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport layer ETL may include an electron transporting material such as an anthracene-based compound, Alq₃ (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

The emission layer EML, the hole transport layer HTL, and/or the electron transport layer ETL may be formed by a process such as thermal deposition, vapor deposition, vacuum deposition, spin coating, inkjet printing, laser printing, casting, laser thermal transfer, or the like. For example, a selective deposition of the emission layer EML for each pixel may be performed relatively effectively by the pixel defining layer PDL having the stepped structure.

In some example embodiments, a hole injection layer may be further formed between the pixel electrode 180 and the hole transport layer HTL. An electron injection layer may be further formed between a counter electrode 190 and the electron transport layer ETL.

The counter electrode 190 may be disposed on the pixel defining layer PDL and the emission layer EML. The counter electrode 190 may be formed on the electron transport layer ETL.

The counter electrode 190 may be a common electrode that may be continuously provided commonly in a plurality of the light emitting regions or the pixels.

The counter electrode 190 may be provided as an electron injection electrode or a cathode. The counter electrode 190 may include a metal, an alloy, an electrically conductive compound, or the like having a relatively lower work function.

For example, the counter electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in a combination of two or more thereof.

The counter electrode 190 may be formed or configured as a transmissive electrode, a translucent electrode, or a reflective electrode. The counter electrode 190 may have a single-layered structure or a multi-layered structure.

The light-emitting element LE may be defined by the stacked structure of the pixel electrode 180, the hole transport layer HTL, the emission layer EML, the electron transport layer ETL, and the counter electrode 190. For example, the light-emitting element LE may be electrically connected to the transistor structure of each pixel through the drain electrode DE.

The light-emitting elements LE may include a first light-emitting element LE1, a second light-emitting element LE2, and a third light-emitting element LE3 including the first emission layer EML1, the second emission layer EML2, and the third emission layer EML3, respectively. In some example embodiments, the first light-emitting element LE1, the second light-emitting element LE2, and the third light-emitting element LE3 may be provided or configured as a red light-emitting element, a green light-emitting element, and a blue light-emitting element, respectively.

An encapsulation layer TFE covering the light-emitting elements LE1, LE2, and LE3 may be disposed on the counter electrode 190. The encapsulation layer TFE may be disposed on the pixel defining layer PDL and the light-emitting elements LE1, LE2, and LE3 to protect the light-emitting elements LE1, LE2, and LE3 from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)), or any combination thereof; or a combination of the inorganic layer and the organic layer.

The encapsulation layer TFE may be formed in a single-layered structure or a multi-layered structure. In some example embodiments, the encapsulation layer TFE may have a sequential stacked structure of a first inorganic layer, an organic layer, and a second inorganic layer.

In some example embodiments, the touch sensor layer TSL may be disposed on the encapsulation layer TFE. For example, the touch sensor layer TSL may be included in the display device as an on-cell type touch sensor. In some example embodiments, a touch substrate layer 200 may be added between the encapsulation layer TFE and the touch sensor layer TSL.

The touch sensor layer TSL may include a first touch sensor electrode layer TS1, a second touch sensor electrode layer TS2, and an intermediate insulating layer ITL between the first touch sensor electrode layer TS1 and the second touch sensor electrode layer TS2. For example, the first touch sensor electrode layer TS1, the intermediate insulating layer ITL, and the second touch sensor electrode layer TS2 may be sequentially stacked from the touch substrate layer 200.

The touch sensor layer TSL may further include an intermediate electrode IE. The intermediate electrode IE may penetrate the intermediate insulating layer ITL to electrically connect the second touch sensor electrode layer TS2 and the first touch sensor electrode layer TS1 with each other.

In some example embodiments, the first touch sensor electrode layer TS1 may include first sensing electrodes and second sensing electrodes arranged in directions crossing each other. The second touch sensor electrode layer TS2 may include a bridge electrode. The bridge electrode may electrically connect neighboring second sensing electrodes or neighboring first sensing electrodes through the intermediate electrode IE.

In some example embodiments, the second touch sensor electrode layer TS2 may include the first and second sensing electrodes, and the first touch sensor electrode layer TS1 may include the bridge electrode.

The touch substrate layer 200 and the intermediate insulating layer ITL may be formed by a deposition process, such as a CVD process, and may include an inorganic insulating material, such as silicon oxide, silicon nitride, silicon oxynitride, or the like. The touch substrate layer 200 and the intermediate insulating layer ITL may be formed by a coating process, such as a spin coating process, and may include an organic insulating material, such as a siloxane resin, an acrylic resin, an epoxy resin, or the like.

A passivation layer PVX covering the second touch sensor electrode layer TS2 may be formed on the intermediate insulating layer ITL. The passivation layer PVX may include the above-mentioned organic insulating material or inorganic insulating material.

A polarizing plate POL may be disposed on the passivation layer PVX. For example, the polarizing plate POL may include a polarizer, including a polyvinyl alcohol (PVA)-based resin oriented in a specific direction, and a protective film formed on upper and/or lower surfaces of the polarizer and including a cellulose-based resin, such as triacetylcellulose (TAC).

Reflection of external light generated from lower structures of the display device may be reduced or suppressed by the polarizing plate POL.

A cover window CW may be stacked on the polarizing plate POL. The cover window CW may include a glass film (e.g., an ultra-thin glass (UTG)) or a hard coating film. The cover window CW may be stacked on the polarizing plate POL by an adhesive layer AL.

In some example embodiments, a color filter layer having an on-cell film (OCF) structure, instead of the polarizing plate POL, may be stacked on the touch sensor layer TSL.

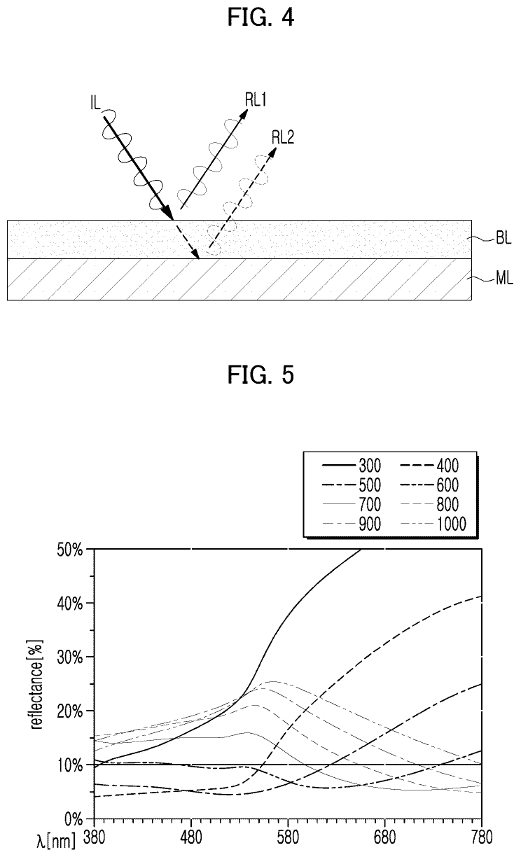

FIG. 4 is a schematic view for describing a light-shielding mechanism by a blocking layer and a metal layer according to some example embodiments.

Referring to FIG. 4, an incident light IL incident on the blocking layer BL from the front portion may be effectively absorbed through the blocking layer BL having relatively higher absorption properties.

A second reflected light RL2 reflected by the metal layer ML among the incident light IL may be controlled through a destructive interference with a first reflected light RL1 partially reflected from a surface of the blocking layer BL.

According to some example embodiments, a refractive index of the blocking layer BL may be adjusted so that the first reflected light RL1 may have the same amplitude as that of the second reflected light RL2. The refractive index of the blocking layer BL may be adjusted in consideration of a refractive index of the metal layer ML and a refractive index of a medium of the incident light IL. In some example embodiments, the refractive index of the blocking layer BL may be adjusted in a range from 2.1 (or about 2.1) to 2.5 (or about 2.5), from 2.2 (or about 2.2) to 2.4 (or about 2.4), or from 2.3 (or about 2.3) to 2.4 (or about 2.4).

According to some example embodiments, a thickness of the blocking layer BL may be adjusted so that the first reflected light RL1 may have a phase difference of 180° from the second reflected light RL2. The thickness of the blocking layer BL may be adjusted in consideration of reflectance and transmittance, as will be described later. As described above, the thickness of the blocking layer BL may be adjusted in a range from 400 Å (or about 400 Å) to 650 Å (or about 650 Å), from 450 Å (or about 450 Å) to 650 Å (or about 650 Å), or from 500 Å (or about 500 Å) to 650 Å (or about 650 Å).

The first reflected light RL1 may be adjusted to have an amplitude that is the same as or similar in some respects to that of the second reflected light RL2, and an opposite phase of the second reflected light RL2, so that the second reflected light RL2 may be reduced or suppressed or removed (e.g., substantially) by the destructive interference. Thus, external light incident from the front portion of the display device may be effectively controlled. Additionally, external light incident from the rear portion may also be blocked or restricted by the metal layer ML.

FIG. 5 is a graph showing a change in reflectance according to a thickness of the blocking layer. FIG. 5 is a graph simulating a reflectance as a function of a wavelength while varying the thickness (Å) of the blocking layer BL formed of molybdenum-tantalum oxide from 300 Å (or about 300 Å) to 1000 Å (or about 1000 Å).

Referring to FIG. 5, reflectances of less than 10% were measured for a light having a wavelength of 550 nm (or about 550 nm) at thicknesses of 400 Å (or about 400 Å), 500 Å (or about 500 Å), and 600 Å (or about 600 Å). From the graph in FIG. 5, it can be observed that the reflectance of less than 10% is achieved at thicknesses ranging from 400 Å (or about 400 Å) to 650 Å (or about 650 Å).

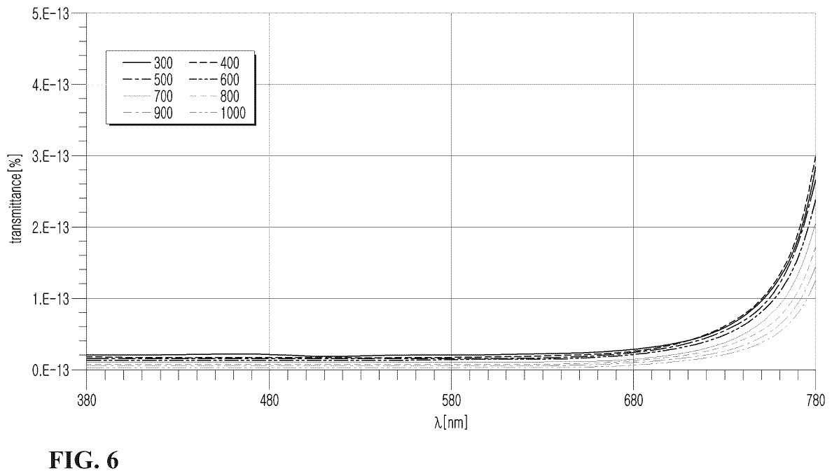

FIG. 6 is a graph showing a change in transmittance according to a thickness of a blocking layer. FIG. 6 is a graph simulating a transmittance as a function of a wavelength while varying the thickness (Å) of the blocking layer BL formed of molybdenum-tantalum oxide from 300 Å (or about 300 Å) to 1000 Å (or about 1000 Å).

Referring to FIG. 6, it can be observed that a transmittance of less than 1.0*10⁻¹²% is obtained at a thickness ranging from about 400 Å (or about 400 Å) to about 650 Å (or about 650 Å).

It may be observed from FIGS. 5 and 6 that the base stack BS having suppressed or reduced reflectance and transmittance can be obtained using the blocking layer BL having the thickness ranging from 400 Å (or about 400 Å) to 650 Å (or about 650 Å).

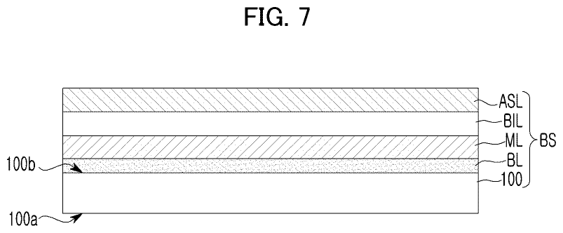

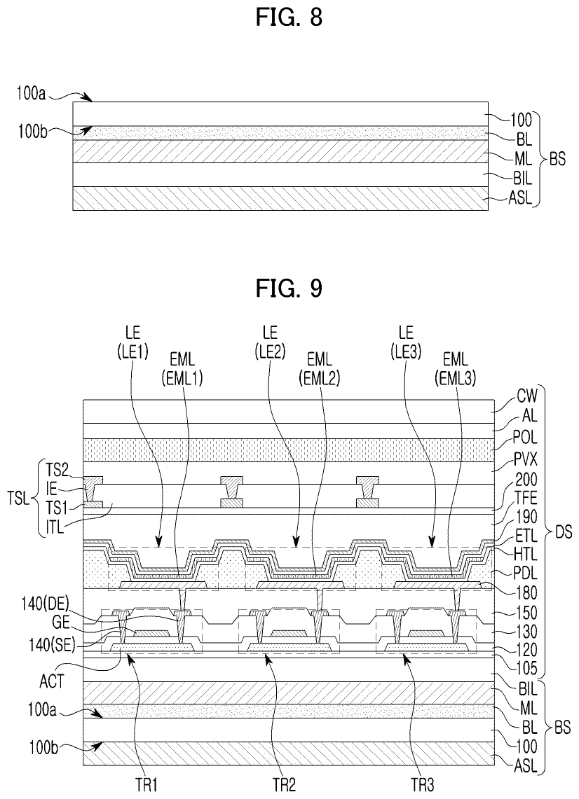

FIGS. 7 and 8 are cross-sectional views illustrating a method of manufacturing a display device according to some example embodiments.

Referring to FIG. 7, the blocking layer BL, the metal layer ML, the buffer insulating layer BIL, and the antistatic layer ASL may be sequentially formed on the second surface 100b of the base substrate 100 to form the base stack BS.

According to some example embodiments of the present disclosure, the blocking layer BL, the metal layer ML, the buffer insulating layer BIL, and the antistatic layer ASL may be formed by a deposition process. According to some example embodiments, the blocking layer BL and the metal layer ML may be formed by a sputtering process. The buffer insulating layer BIL may be formed through a CVD process. The antistatic layer ASL may be formed through a CVD process or a sputtering process.

For example, if a blocking or a light-shielding layer is formed on the base substrate 100 using a black ink by an inkjet process or a printing process, sufficient coating properties may not be provided on a large-area substrate. Accordingly, the inkjet process or the printing process may be performed on each of the substrates of individual cell units. In this case, process yield and economic feasibility may be reduced. Additionally, the inkjet process or the printing processes are performed on the individual cell unit substrate having a reduced thickness and process stability may be reduced.

However, according to some example embodiments of the present disclosure, the blocking layer BL, the metal layer ML, the buffer insulating layer BIL, and the antistatic layer ASL may be formed on the relatively large-area base substrate 100 by the deposition process. The deposition process may provide sufficient coating properties, and the deposition process may not be performed on each substrate of individual cell units. Thus, process yield and economic feasibility may be improved. The deposition process may form a relatively thicker blocking layer BL, metal layer ML, buffer insulating layer BIL, and antistatic layer ASL, and, as a result, the process stability is improved.

Further, resistance and hardness properties of the antistatic layer ASL may be controlled with relative ease by adjusting conditions of the deposition process.

The base substrate 100 may be, e.g., a mother substrate before being cut into the individual cell units. Thus, the blocking layer BL, the metal layer ML, the buffer insulating layer BIL, and the antistatic layer ASL may be formed while sufficiently maintaining a thickness of the base substrate 100 (e.g., from 0.5 T (or about 0.5 T) to 1 T (or about 1 T)).

Referring to FIG. 8, the base stack BS may be inverted so that the first surface 100a of the base substrate 100 may face upward. Thereafter, the thickness may be reduced by polishing an upper portion of the base substrate 100.

In some example embodiments, the upper portion of the base substrate 100 may be polished so that the base substrate 100 may have a thickness in a range of 0.1 T (or about 0.1 T) to 0.3 T (or about 0.3 T).

Thereafter, as described with reference to FIG. 3, the display structure DS may be formed on the first surface 100a of the base substrate 100. The display structure DS may be repeatedly formed for each individual cell unit region of the base substrate 100.

According to some example embodiments, after forming the display structure DS, the base stack BS may be cut into individual cell units. Accordingly, a display device may be obtained as a product unit. Thereafter, as illustrated in FIG. 1, a module process including the connection of the printed circuit board 300 may be performed.

FIG. 9 is a schematic cross-sectional view illustrating a display device according to some example embodiments. The display device of FIG. 9 may be the same as or similar in some respects to the display device of FIG. 3, and therefore may be best understood with reference thereto, where like numerals indicate like elements not described again in detail.

Referring to FIG. 9, and as described above with reference to FIG. 3, the base stack BS may include the base substrate 100, the blocking layer BL, the metal layer ML, the buffer insulating layer BIL, and the antistatic layer ASL.

According to some example embodiments, the blocking layer BL, the metal layer ML, and the buffer insulating layer BIL may be sequentially stacked on the first surface 100a of the base substrate 100. The antistatic layer ASL may be formed on the second surface 100b of the base substrate 100.

The display structure DS may be formed on the buffer insulating layer BIL. In some example embodiments, the buffer insulating layer BIL may be provided or configured as a barrier layer of the display structure DS. In some example embodiments, the barrier layer 105 may be omitted.

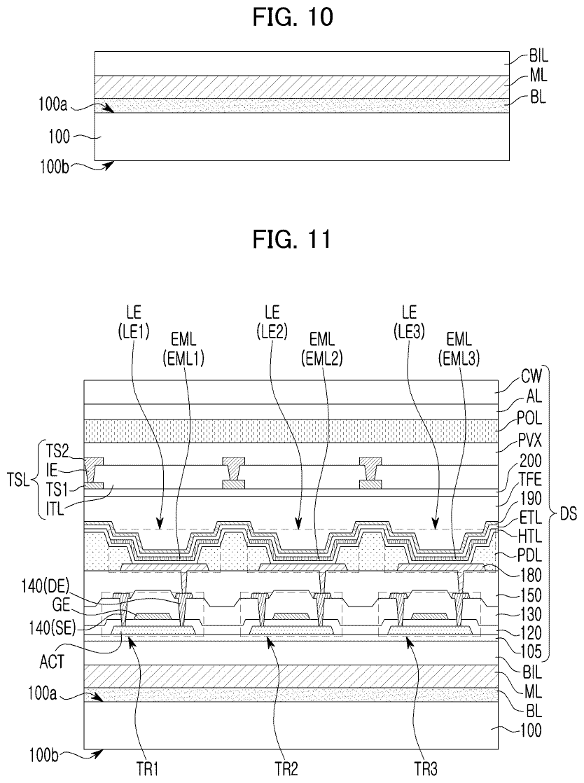

FIGS. 10 to 13 are cross-sectional views illustrating a method of manufacturing a display device according to some example embodiments.

Referring to FIG. 10, the blocking layer BL, the metal layer ML, and the buffer insulating layer BIL may be sequentially formed on the first surface 100a of the base substrate 100 by a deposition process as described above. The base substrate 100 may be a mother substrate before being cut into individual cell units. Thus, the blocking layer BL, the metal layer ML, and the buffer insulating layer BIL may be formed having improved stability while having sufficient (or desirable) thickness of the base substrate 100 (e.g., from 0.5 T (or about 0.5 T) to 1 T (or about 1 T)).

Referring to FIG. 11, as described with reference to FIG. 3, the display structure DS may be formed on the buffer insulating layer BIL. According to some example embodiments, the display structure DS may be repeatedly formed for each individual cell unit region of the base substrate 100.

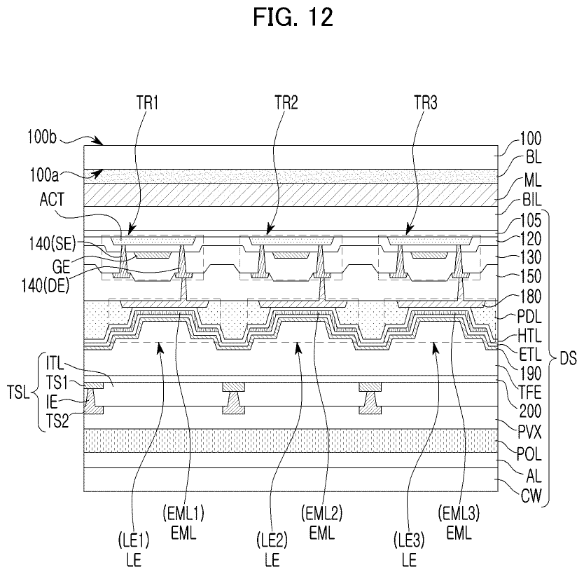

Referring to FIG. 12, the base substrate 100 on which the display structure DS is formed may be inverted so that the second surface 100b may face upward. Thereafter, the thickness of the base substrate 100 may be reduced by polishing a portion including the second surface 100b of the base substrate 100 (e.g., from 0.1 T (or about 0.1 T) to 0.3 T (or about 0.3 T)).

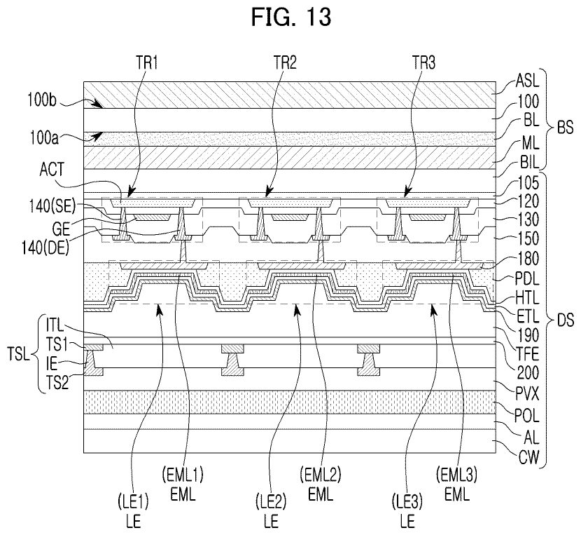

Referring to FIG. 13, the antistatic layer ASL may be formed on the second surface 100b of the base substrate 100 by a deposition process as described above.

Thereafter, the base stack BS on which the display structure DS is formed may be cut into the individual cell units. Accordingly, a display device may be obtained as a product unit. Thereafter, as illustrated in FIG. 1, a module process including the connection of the printed circuit board 300 may be performed.

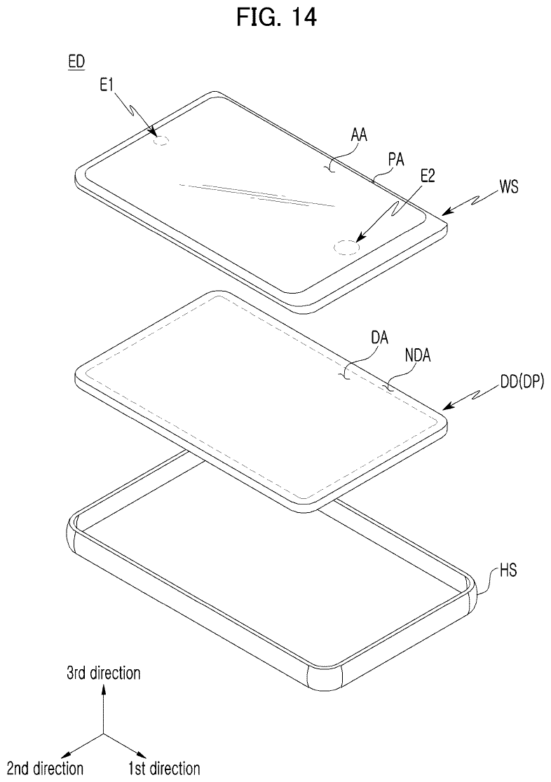

FIG. 14 is an exploded perspective view illustrating an electronic device according to some example embodiments.

According to some example embodiments, the electronic device ED may be implemented in the form of a mobile phone (smart phone), a tablet, a personal computer (PC), or the like including the above-described display device.

Referring to FIG. 14, an electronic device ED may include a window structure WS, a display device DD, and a housing HS. The display device DD may include a display panel DP including the above-described transistor structure and the light-emitting element. The housing HS, the display device DD, and the window structure WS may be sequentially stacked in the third direction.

The window structure WS may provide an external display surface recognized by a user, such as a viewing surface of an electronic device, such as a mobile phone, and may include a transparent material film. For example, the window structure WS may include glass (e.g., an ultra-thin glass (UTG), a hard coating film, a plastic film, or the like).

An outer surface of the window structure WS may include an active area AA and a peripheral area PA. The active area AA may provide a surface on which an image of the display device DD is substantially displayed and a user's touch/command is input. The peripheral area PA may substantially correspond to a bezel area of the electronic device ED.

As described with reference to FIG. 1, the display device DD or the display panel DP may include the display area DA and the non-display area NDA. The display area DA of the display panel DP may substantially correspond to or overlap the active area AA of the window structure WS. The non-display area NDA of the display panel DP may substantially correspond to or overlap the peripheral area PA of the window structure WS. In some example embodiments, the peripheral area PA may further include a margin area that may not overlap the non-display area NDA.

In some example embodiments, functional element areas E1 and E2 may be included in the active area AA of the window structure WS. For example, a first functional element area E1 may be included in one end portion of the active area AA, and may be implemented, e.g., in the form of a camera hole. The second functional element area E2 may be provided as a fingerprint sensing area.

For example, a sensor structure for touch sensing or fingerprint sensing may be disposed within the display panel DP or between the window structure WS and the display panel DP.

The housing HS may be provided as a frame structure or a rear housing of the display device DD or the electronic device ED. A cover panel may be disposed between the housing HS and the display panel DP. The housing HS or the cover panel may include a plate (e.g., an SUS plate) supporting the display panel DP, the printed circuit board 300 (see FIG. 1), or the like. The housing HS or the cover panel may include an elastic body for shock absorption of the display device DD.

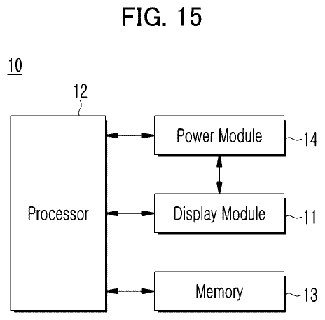

FIG. 15 is a block diagram of an electronic device according to some example embodiments.

FIG. 15 is a block diagram of an electronic device according to some example embodiments.

Referring to FIG. 15, an electronic device 10 according to some example embodiments may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

Data (e.g., one or more applications) for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module that converts a power supplied by the power supply module to generate power for the operation of the electronic device 10.

At least one of the components of the electronic device 10, as described above, may be included in the display device according to the above-described embodiments. Additionally, some individual modules functionally included in one module may be included in the display device, and others may be provided separately from the display device. For example, the display module 11 may include the display device, and the processor 12, the memory 13, and the power module 14 may be provided in the form of another device in the electronic device 10, different from the display device.

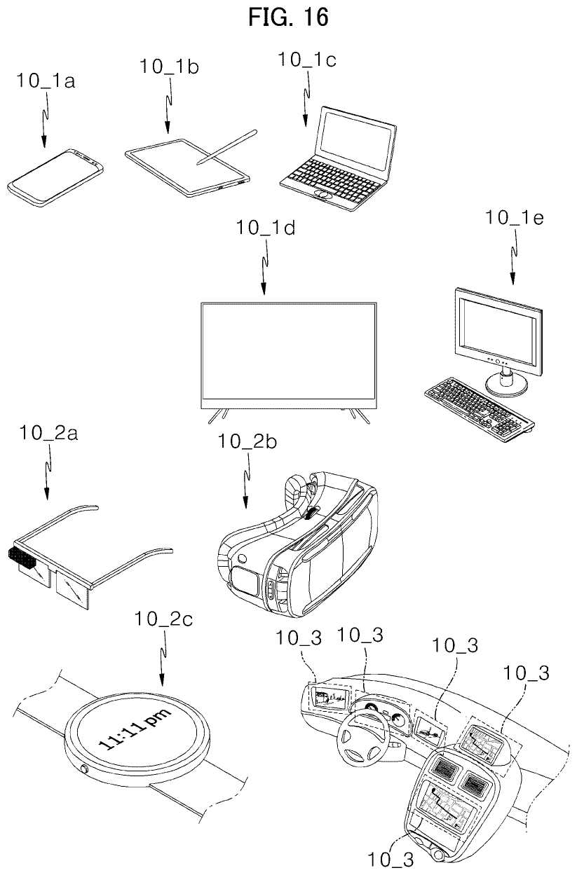

FIG. 16 is a schematic diagram of electronic devices according to some example embodiments.

Referring to FIG. 16, non-limiting examples of various electronic devices including the display device according to the above-described embodiments include an electronic device for displaying an image such as a smartphone 10_1a, a tablet PC 10_1b, a laptop 10_1c, a television 10_1d, a desk monitor 10_1e, or the like; a wearable electronic device including a display module such as smart glasses 10_2a, a head mounted display 10_2b, a smart watch 10_2c, or the like; a vehicle electronic device 10_3 including a display module such as a center information display (CID) disposed at a vehicle instrument panel, a center fascia, a dashboard, etc., a head-up display, a room mirror display, or the like. The electronic device may include a virtual reality glass or an augmented reality glass.

As described herein, any devices, systems, modules, portions, units, controllers, circuits, and/or portions thereof according to any of the example embodiments, and/or any portions thereof (including, without limitation, the display module 11, the processor 12, the memory 13, the power module 14, the smartphone 10_1a, the tablet PC 10_1b, the laptop 10_1c, the television 10_1d, the desk monitor 10_1e, the smart glasses 10_2a, the head mounted display 10_2b, the smart watch 10_2c, the vehicle electronic device 10_3, the virtual reality glasses, the augmented reality glasses, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), a System-on-Chip (SoC), a programmable logic unit, a microprocessor, an application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example, a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A display device, comprising:
a base stack comprising,
a base substrate;
a blocking layer on the base substrate, the blocking layer including at least one of a metal oxide, a metal nitride, or a metal carbide; and
a metal layer on the blocking layer and spaced apart from the base substrate with the blocking layer therebetween; and
a display structure on the base stack, the display structure comprising a light-emitting element.

2. The display device of claim 1, wherein the blocking layer includes at least one of a molybdenum oxide-based material, a copper oxide-based material, a copper nitride-based material, or a niobium carbide-based material.

3. The display device of claim 1, wherein the blocking layer includes molybdenum-tantalum oxide.

4. The display device of claim 1, wherein the blocking layer contacts the base substrate, and the metal layer contacts the blocking layer.

5. The display device of claim 1, wherein the blocking layer has a reflectance of less than 10% and a transmittance of less than 10% for a light having a wavelength of 550 nm.

6. The display device of claim 5, wherein the blocking layer has a transmittance of less than 1.0*10⁻¹²% for the light having the wavelength of 550 nm.

7. The display device of claim 1, wherein the blocking layer has a thickness of 400 Å to 650 Å.

8. The display device of claim 1, wherein the base stack further comprises a buffer insulating layer and an antistatic layer including a metal nitride.

9. The display device of claim 8, wherein the buffer insulating layer includes at least one of silicon oxide, silicon nitride, silicon oxynitride, or a metal oxide.

10. The display device of claim 8, wherein the antistatic layer includes titanium nitride.

11. The display device of claim 8, wherein a resistivity of the antistatic layer is in a range from 100 μΩ·cm to 500 μΩ·cm, and a sheet resistance of the antistatic layer is in a range from 5 Ω/□ to 100 Ω/□.

12. The display device of claim 8, wherein a pencil hardness of the base stack measured from a surface of the antistatic layer is 5 H or higher.

13. The display device of claim 8, wherein the base substrate has a first surface and a second surface opposite each other,
the display structure is on the first surface of the base substrate, and
the blocking layer, the metal layer, the buffer insulating layer, and the antistatic layer are sequentially on the second surface of the base substrate.

14. The display device of claim 8, wherein the base substrate has a first surface and a second surface opposite each other,
the blocking layer, the metal layer, and the buffer insulating layer are sequentially on the first surface of the base substrate,
the antistatic layer is on the second surface of the base substrate, and
the display structure is on the buffer insulating layer.

15. A method for manufacturing a display device, comprising:
providing a base substrate having a first surface and a second surface opposite the first surface;
forming a blocking layer including at least one of a metal oxide, a metal nitride, or a metal carbide on the first surface or the second surface of the base substrate;
forming a metal layer on the blocking layer; and
forming a display structure including a light-emitting element on the first surface of the base substrate.

16. The method of claim 15, further comprising sequentially forming a buffer insulating layer and an antistatic layer that includes a metal nitride on the metal layer,
wherein the blocking layer, the metal layer, the buffer insulating layer, and the antistatic layer are sequentially formed from the second surface of the base substrate.

17. The method of claim 15, further comprising:
forming a buffer insulating layer on the metal layer on the first surface of the base substrate; and
forming an antistatic layer that includes a metal nitride on the second surface of the base substrate after forming the display structure,
wherein the blocking layer, the metal layer, and the buffer insulating layer are sequentially formed from the first surface of the base substrate.

18. The method of claim 17, further comprising reducing a thickness of the base substrate before forming the antistatic layer.

19. An electronic device, comprising:
a display device;
a memory; and
a processor configured to execute data stored in the memory to control an operation of the display device,
wherein the display device comprises,
a base stack comprising,
a base substrate;
a blocking layer on the base substrate, the blocking layer including at least one of a metal oxide, a metal nitride, or a metal carbide; and
a metal layer on the blocking layer and spaced apart from the base substrate with the blocking layer therebetween; and
a display structure on the base stack, the display structure comprising a light-emitting element.

20. The electronic device of claim 19, wherein the electronic device includes virtual reality or augmented reality glasses, a smartphone, a tablet personal computer (PC), a laptop, a television, a desk monitor, smart glasses, a head mounted display, a smart watch, or a vehicle display.
